(19) United States
(12) Patent Application Publication
(10) Pub. No.: US 2026/0177493 A1
(43) Pub. Date: Jun. 25, 2026

(54) SURFACE-ENHANCED RAMAN SCATTERING SUBSTRATE BASED ON COMPOSITE STRUCTURE, AND METHOD FOR MANUFACTURING SAME

(71) Applicant: PICO FOUNDRY INC., Daejeon (KR)

(72) Inventor: Yong Won CHOI, Suwon-si (KR)

(73) Assignee: PICO FOUNDRY INC., Daejeon (KR)

(21) Appl. No.: 19/129,857

(22) PCT Filed: Nov. 30, 2022
(86) PCT No.: PCT/KR2022/019265

§ 371 Date: Jul. 3, 2025

(30) Foreign Application Priority Data
Nov. 15, 2022 (KR) 10-2022-0153072

(51) Int. Cl. G01N 21/65; H10W 20/00; H10W 72/00

(52) U.S. Cl. CPC G01N 21/658; H10W 20/056; H10W 72/07251

(57) ABSTRACT

The present invention relates to a surface-enhanced Raman scattering substrate and a method for manufacturing the same. According to an embodiment, the surface-enhanced Raman scattering substrate includes a substrate; a lower plasmonic layer formed on the substrate and including a first metal material; a protective layer formed on the lower plasmonic layer and including at least one material of a second metal material, an oxide, and a nitride; and an upper plasmonic layer formed on the protective layer and including a three-dimensional nanostructure based on the first metal material.

### TECHNICAL FIELD

The present invention relates to a surface-enhanced Raman scattering (SERS) substrate, and more particularly, to a technical idea for suppressing oxidation of a metal material included in the SERS substrate by applying a composite structure.

In addition, the present invention was derived from research conducted as part of the “Nano-Convergence 2020+” program.
Project Identification Number: 1711130830
Project Number: 2021M3C3A2040383
Project Management (Specialized) Agency: National Research Foundation of Korea
Research Program Title: Nano-Convergence 2020+ (Plus Program)
Research Project Title: Development and Commercialization of a Plasmonic Nanostructure/Oxide Double-Layer Chip for Molecular Spectroscopic Analysis with High Specificity and Sensitivity
Performing Organization: PICO Foundry Co., Ltd.
Research Period: Jul. 1, 2021 to Dec. 31, 2022

### BACKGROUND ART

Raman spectroscopy is an analytical technique applied to the study of molecular vibrational structures or for qualitative and quantitative analysis of substances. When light is irradiated onto an analyte and reflected, the intensity of the reflected light is analyzed as a spectrum according to frequency, thereby enabling analysis of the composition and structural information of the substance.

Raman spectroscopy is emerging as a next-generation analytical technology due to its rapid, accurate, and non-destructive analytical capabilities. However, conventional Raman spectroscopy has a limitation in that it is difficult to analyze substances present in trace amounts due to the inherently low Raman scattering probability of molecules and the potential occurrence of strong fluorescence.

To address this issue of low signal intensity, a method utilizing the surface-enhanced Raman scattering (SERS) effect has been proposed.

SERS may significantly enhance the intensity of the Raman spectrum through absorbed energy on the surface. The enhancement factor (EF), which is commonly used as a measure of the SERS effect, typically ranges from 10⁴ to 10⁸. Since the enhancement factor is determined by the material and nanostructure pattern of the substrate surface, the fabrication of highly sensitive active substrates has emerged as a key challenge in SERS analytical technology. In other words, ongoing research is being conducted to optimize the material and nanostructure pattern of the substrate surface in order to improve the analytical performance of SERS substrates.

Specifically, SERS substrates are required to have improved sensitivity for detecting ultratrace amounts of substances. Accordingly, SERS substrates based on silver (Ag), which exhibit superior sensitivity enhancement characteristics, are preferred over gold (Au)-based SERS substrates.

However, conventional Ag-based SERS substrates suffer from degradation in SERS performance due to oxidation reactions occurring on the Ag surface, which may lead to the formation of background peaks (i.e., noise components), making accurate analysis difficult.

### DISCLOSURE

### Technical Problem

The present invention is directed to providing a high-performance surface-enhanced Raman scattering (SERS) substrate and a method for manufacturing the same, which exhibit a high signal enhancement effect, excellent signal uniformity, and high reproducibility.

In addition, the present invention is directed to providing a SERS substrate and a method for manufacturing the same, which minimize the formation of background peaks by preventing oxidation of the metal material constituting the plasmonic layer through the application of a protective layer.

Further, the present invention is directed to providing a SERS substrate and a method for manufacturing the same, which minimize the formation of background peaks by preventing oxidation of the metal material constituting the plasmonic layer through the application of an oxidation-inhibiting layer.

### Technical Solution

According to an embodiment of the present invention, a surface-enhanced Raman scattering (SERS) substrate may include: a substrate; a lower plasmonic layer formed on the substrate and comprising a first metal material; a protective layer formed on the lower plasmonic layer and comprising at least one material selected from the group consisting of a second metal material, an oxide, and a nitride; and an upper plasmonic layer formed on the protective layer and comprising a three-dimensional nanostructure based on the first metal material.

According to one aspect, the first metal material may include silver (Ag).

According to one aspect, the second metal material may include at least one material selected from the group consisting of gold (Au), palladium (Pd), platinum (Pt), titanium (Ti), chromium (Cr), and nickel (Ni).

According to one aspect, the oxide and nitride may include at least one material selected from the group consisting of silicon nitride (Si₃N₄), titanium nitride (TiN), silicon oxide (SiO₂), silicon oxynitride (SiON), aluminum oxide (Al₂O₃), chromium oxide (Cr₂O₃), nickel oxide (NiO₂), aluminum nitride (AlN), titanium nitride (TiN), and titanium oxide (TiO₂).

According to one aspect, the protective layer may be formed on the lower plasmonic layer to have a thickness in a range of 2 nm to 10 nm.

According to one aspect, the three-dimensional nanostructure may be a nanoarray structure in which a plurality of first nanostructures formed in a first direction intersect with a plurality of second nanostructures formed in a second direction orthogonal to the first direction.

According to one aspect, each of the plurality of first nanostructures and the plurality of second nanostructures may be formed to have a thickness in a range of 16 nm to 20 nm.

According to one aspect, the upper plasmonic layer may further include a first upper protective layer formed on each of the plurality of first nanostructures and a second upper protective layer formed on each of the plurality of second nanostructures.

According to one aspect, the upper plasmonic layer may further include: a first upper protective layer formed beneath each of the plurality of first nanostructures; a second upper protective layer formed on each of the plurality of first nanostructures; a third upper protective layer formed beneath each of the plurality of second nanostructures; and a fourth upper protective layer formed on each of the plurality of second nanostructures.

According to one aspect, the substrate may be a substrate comprising a metal thin film coated on a silicon wafer.

According to an embodiment of the present invention, a method of manufacturing a surface-enhanced Raman scattering (SERS) substrate may include: forming a lower plasmonic layer comprising a first metal material on a substrate; forming a protective layer on the lower plasmonic layer, the protective layer comprising at least one material selected from the group consisting of a second metal material, an oxide, and a nitride; and forming an upper plasmonic layer on the protective layer, the upper plasmonic layer comprising a three-dimensional nanostructure based on the first metal material.

According to one aspect, forming the upper plasmonic layer may include: forming a plurality of first nanostructures in a first direction on the protective layer; and forming a plurality of second nanostructures in a second direction orthogonal to the first direction on the plurality of first nanostructures.

According to one aspect, forming the plurality of first nanostructures may include forming the plurality of first nanostructures each having a first upper protective layer on a top thereof on the protective layer, and forming the plurality of second nanostructures may include forming the plurality of second nanostructures each having a second upper protective layer on a top thereof on the plurality of first nanostructures having the first upper protective layer.

According to one aspect, forming the plurality of first nanostructures may include forming the plurality of first nanostructures each having a first upper protective layer on a bottom thereof and a second upper protective layer on a top thereof on the protective layer, and forming the plurality of second nanostructures may include forming the plurality of second nanostructures each having a third upper protective layer on a bottom thereof and a fourth upper protective layer on a top thereof on the plurality of first nanostructures having the first and second upper protective layers.

### Advantageous Effects

According to an embodiment, the present invention may provide a high-performance surface-enhanced Raman scattering (SERS) substrate exhibiting a high signal enhancement effect, excellent signal uniformity, and high reproducibility.

According to an embodiment, the present invention may minimize the formation of background peaks by preventing oxidation of the metal material constituting the plasmonic layer through the application of a protective layer.

According to an embodiment, the present invention may minimize the formation of background peaks by preventing oxidation of the metal material constituting the plasmonic layer through the application of an oxidation-inhibiting layer.

### DESCRIPTION OF DRAWINGS

FIGS. 1A to 1D are views illustrating a surface-enhanced Raman scattering (SERS) substrate according to an embodiment of the present invention.

FIG. 2 is a view illustrating a surface-enhanced Raman scattering (SERS) substrate according to a first embodiment of the present invention.

FIG. 3 is a view illustrating a surface-enhanced Raman scattering (SERS) substrate according to a second embodiment of the present invention.

FIG. 4 is a view illustrating a surface-enhanced Raman scattering (SERS) substrate according to a third embodiment of the present invention.

FIG. 5 is a view illustrating a surface-enhanced Raman scattering (SERS) substrate according to a fourth embodiment of the present invention.

FIGS. 6A to 6C are views illustrating measurement results of background peaks for the surface-enhanced Raman scattering (SERS) substrates according to the first to third embodiments of the present invention.

FIGS. 7A and 7B are views illustrating measurement results of background peaks for the surface-enhanced Raman scattering (SERS) substrate according to the fourth embodiment of the present invention.

FIGS. 8A to 8C are views illustrating a method of manufacturing a surface-enhanced Raman scattering (SERS) substrate according to the first embodiment of the present invention.

FIGS. 9A to 9C are views illustrating a method of manufacturing a surface-enhanced Raman scattering (SERS) substrate according to the second embodiment of the present invention.

FIGS. 10A to 10C are views illustrating a method of manufacturing a surface-enhanced Raman scattering (SERS) substrate according to the third embodiment of the present invention.

FIGS. 11A to 11D are views illustrating a method of manufacturing a surface-enhanced Raman scattering (SERS) substrate according to the fourth embodiment of the present invention.

### BEST MODE

Specific structural or functional descriptions of embodiments according to the concept of the present invention disclosed in this specification are merely illustrated for the purpose of explaining the embodiments according to the concept of the present invention, and the embodiments according to the concept of the present invention may be implemented in various forms and are not limited to the embodiments described in this specification.

Various modifications and variations may be made to the embodiments according to the concept of the present invention, and the embodiments may take on various forms. Accordingly, the embodiments are illustrated in the drawings and are described in detail in this specification. However, this is not intended to limit the embodiments to the specific forms of disclosure, and the present invention includes modifications, equivalents, or substitutions that fall within the spirit and scope of the invention.

Terms such as “first” or “second” may be used to describe various components, but the components should not be limited by these terms. The terms are only used to distinguish one component from another. For example, a first component may be referred to as a second component without departing from the scope of the invention, and similarly, a second component may also be referred to as a first component.

When it is mentioned that a certain component is “connected” or “coupled” to another component, it should be understood that the component may be directly connected or coupled to the other component, or there may be another component interposed therebetween. On the other hand, when a component is referred to as being “directly connected” or “directly coupled” to another component, it should be understood that there is no component in between. Expressions describing the relationships between components, such as “between” and “directly between” or “adjacent to,” should be interpreted in the same manner.

The terms used in this specification are used only to describe specific embodiments, and are not intended to limit the invention. As used herein, the singular forms also include plural forms unless the context clearly indicates otherwise. In this specification, terms such as “comprise” or “have” are intended to specify the presence of stated features, integers, steps, operations, components, or combinations thereof, but do not preclude the presence or addition of one or more other features, integers, steps, operations, components, or combinations thereof.

Unless otherwise defined, all terms used herein, including technical and scientific terms, have the same meaning as commonly understood by one of ordinary skill in the art to which the invention pertains. Terms generally used in dictionaries should be interpreted to have meanings consistent with the meanings in the context of the relevant technical field, and should not be interpreted in an idealized or overly formal sense unless expressly defined herein.

Hereinafter, embodiments will be described in detail with reference to the accompanying drawings. However, the scope of the patent application is not limited or restricted by such embodiments. The same reference numerals denote the same elements throughout the drawings.

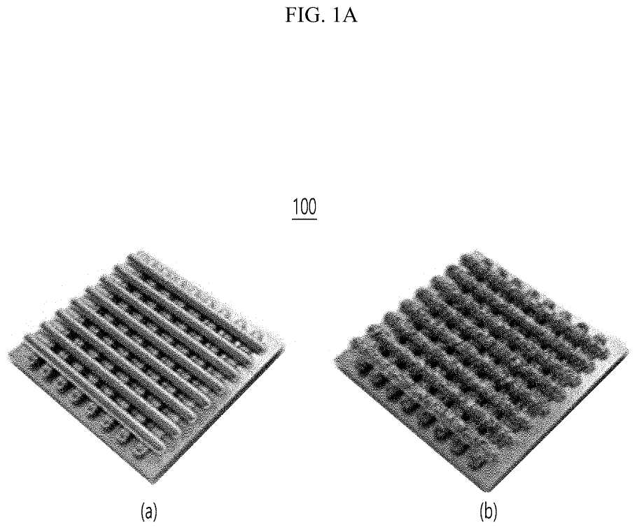

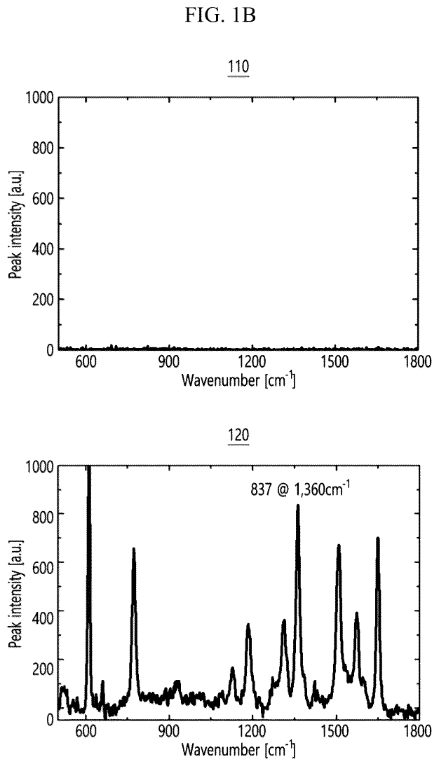

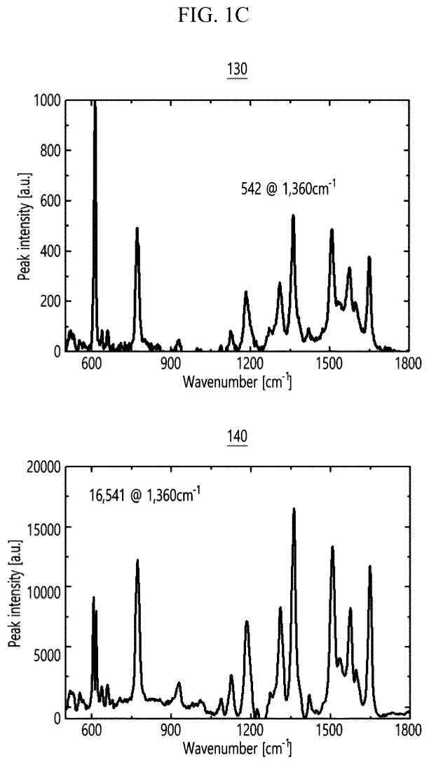

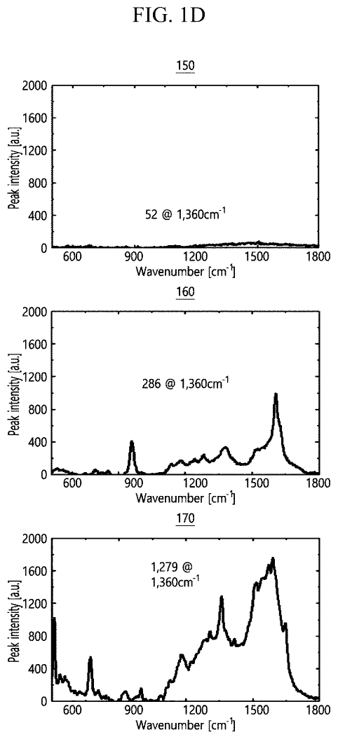

FIGS. 1A to 1D are views illustrating a surface-enhanced Raman scattering (SERS) substrate according to an embodiment of the present invention.

Referring to FIGS. 1A to 1D, reference numeral 100 denotes a schematic view of a surface-enhanced Raman scattering (SERS) substrate according to an embodiment of the present invention.

Reference numerals 110 and 120 respectively denote background peak measurement results and Raman shift measurement results when gold (Au) is used as the first metal material, and reference numerals 130 and 140 respectively denote background peak measurement results and Raman shift measurement results when silver (Ag) is used as the first metal material.

In addition, reference numerals 150 to 170 denote changes in background peaks of the SERS substrate according to the progression of oxidation of silver (Ag) when silver (Ag) is used as the first metal material.

Specifically, reference numeral 150 denotes the background peak measurement result of the SERS substrate in an as-deposited (As-Dep) state, reference numeral 160 denotes the background peak measurement result of the SERS substrate after 30 days from the application of silver (Ag), and reference numeral 170 denotes the background peak measurement result of the SERS substrate after 60 days from the application of silver (Ag).

The surface-enhanced Raman scattering (SERS) substrate 100 according to an embodiment of the present invention may exhibit a high signal enhancement effect, excellent signal uniformity, and high reproducibility.

In addition, the SERS substrate 100 may minimize the formation of background peaks by preventing oxidation of the first metal material constituting the plasmonic layer through the application of at least one of a protective layer and an oxidation-inhibiting layer.

Specifically, the surface-enhanced Raman scattering (SERS) substrate 100 may be formed as a stacked structure comprising a base substrate, a lower plasmonic layer formed on the base substrate and comprising a first metal material, and an upper plasmonic layer formed on the lower plasmonic layer and comprising a three-dimensional nanostructure based on the first metal material. Here, the lower plasmonic layer and the upper plasmonic layer including the three-dimensional nanostructure may induce surface plasmon resonance.

In addition, an analyte may be applied to the SERS substrate 100, and the analyte may be detected using a Raman signal obtained through surface-enhanced Raman scattering by analyzing light scattered by the analyte upon irradiation of laser light from an external device.

For example, the three-dimensional nanostructure may be a nanoarray structure in which a plurality of first nanostructures formed in a first direction intersect with a plurality of second nanostructures formed in a second direction orthogonal to the first direction.

Furthermore, the first nanostructures and the second nanostructures may include at least one of a structure based on nano-wires as shown in FIGS. 1A, 100(a), and a structure based on nanoparticles as shown in FIGS. 1A, 100(b).

According to one aspect, the plurality of first nanostructures and the plurality of second nanostructures may be stacked multiple times. In other words, the upper plasmonic layer may be formed as a stacked structure in which a plurality of three-dimensional nanostructures are laminated.

In addition, the SERS substrate 100 may be formed as a structure in which a plurality of lower plasmonic layers and a plurality of upper plasmonic layers are laminated. In other words, the SERS substrate 100 may be formed as a laminated structure comprising a first lower plasmonic layer, a first upper plasmonic layer, a second lower plasmonic layer, a second upper plasmonic layer, and so on.

The first metal material constituting the plasmonic layer may include at least one material selected from the group consisting of gold (Au) and silver (Ag).

According to reference numerals 110 to 140, gold (Au), in terms of material properties, exhibits excellent environmental resistance (such as moisture resistance, humidity resistance, and chemical resistance), but has a drawback of low sensitivity in surface-enhanced Raman scattering (SERS), thus presenting limitations in the analysis of trace amounts of substances. In contrast, silver (Ag) provides improved SERS performance compared to gold (Au) (reference numeral 140; 837@ 1,360cm⁻¹→16,541@1,360 cm⁻¹), but has poor environmental stability, such that even short-term exposure to the atmosphere leads to oxidation reactions that degrade SERS performance and generate background peaks (reference numeral 130; 542@1,360 cm⁻¹), making accurate analysis difficult.

In addition, according to reference numerals 150 to 170, it may be observed that as oxidation progresses, the background peak becomes sharper, and the peak intensity increases over time compared to the initial state of fabrication.

Accordingly, in order to enhance the SERS performance, the SERS substrate 100 may use silver (Ag) as the first metal material, and may apply a protective layer or an oxidation-inhibiting layer to suppress the oxidation of silver (Ag).

According to one aspect, the SERS substrate 100 may apply both a protective layer and an oxidation-inhibiting layer so as to minimize the oxidation of silver (Ag) and the resulting formation of background peaks.

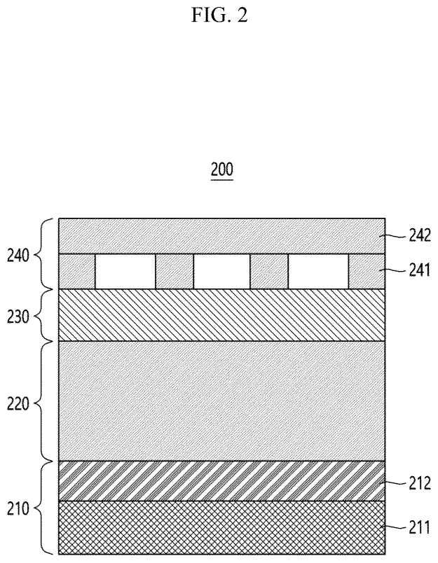

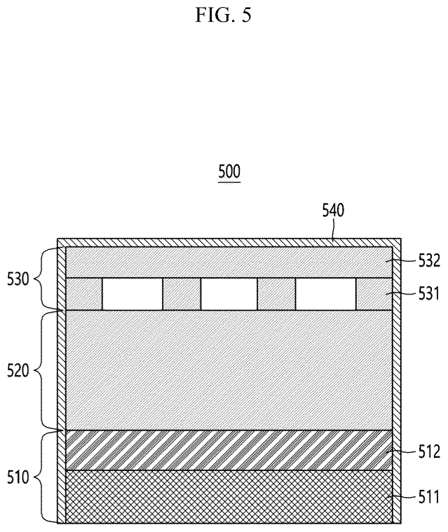

An example in which a protective-layer-based composite structure is applied to the surface-enhanced Raman scattering (SERS) substrate 100 will be described in more detail with reference to the embodiments shown in FIGS. 2 to 4, and an example in which an oxidation-inhibiting layer is applied will be described in more detail with reference to the embodiment shown in FIG. 5.

FIG. 2 is a view illustrating a surface-enhanced Raman scattering (SERS) substrate according to a first embodiment of the present invention.

Referring to FIG. 2, a SERS substrate 200 according to the first embodiment may be formed by stacking a substrate 210, a lower plasmonic layer 220, a protective layer 230, and an upper plasmonic layer 240.

According to one aspect, the upper plasmonic layer 240 may include a nanoarray structure in which a plurality of first nanostructures 241 formed in a first direction intersect with a plurality of second nanostructures 242 formed in a second direction orthogonal to the first direction. In addition, the substrate 210 may be a substrate in which a metal thin film 212 is coated on a silicon wafer 211. Preferably, the metal thin film 212 may be a titanium (Ti) thin film having a thickness of 1 nm.

The lower plasmonic layer 220 according to the embodiment may comprise a first metal material, which may include silver (Ag). Preferably, the lower plasmonic layer 220 may be a silver (Ag) metal layer having a thickness of 30 nm.

The protective layer 230 according to the embodiment may comprise at least one material selected from the group consisting of a second metal material, an oxide, and a nitride.

For example, the second metal material may include at least one material selected from the group consisting of gold (Au), palladium (Pd), platinum (Pt), titanium (Ti), chromium (Cr), and nickel (Ni).

In addition, the oxide and nitride may include at least one material selected from the group consisting of silicon nitride (Si₃N₄), titanium nitride (TiN), silicon oxide (SiO₂), silicon oxynitride (SiON), aluminum oxide (Al₂O₃), chromium oxide (Cr₂O₃), nickel oxide (NiO₂), aluminum nitride (AlN), titanium nitride (TiN), and titanium oxide (TiO₂).

Preferably, the protective layer 230 may be a gold (Au) metal layer.

According to one aspect, the protective layer 230 may be formed to have a thickness in a range of 2 nm to 10 nm, and preferably, the protective layer 230 may be formed to have a thickness of 10 nm.

According to one aspect, the plurality of first nanostructures 241 and the plurality of second nanostructures 242 constituting the upper plasmonic layer 240 may be formed to have a thickness in a range of 16 nm to 20 nm. Preferably, the plurality of first nanostructures 241 and the plurality of second nanostructures 242 may each be formed to have a thickness of 20 nm.

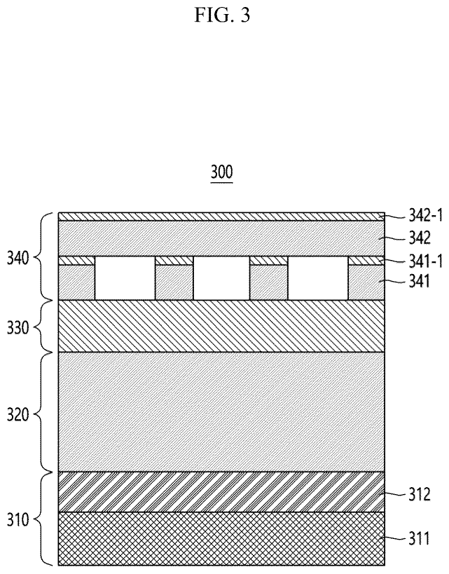

FIG. 3 is a view illustrating a surface-enhanced Raman scattering (SERS) substrate according to a second embodiment of the present invention.

Referring to FIG. 3, a SERS substrate 300 according to the second embodiment may be formed by stacking a substrate 310, a lower plasmonic layer 320, a protective layer 330, and an upper plasmonic layer 340.

According to one aspect, the upper plasmonic layer 340 may be formed by stacking a plurality of first nanostructures 341, first upper protective layers 341-1 respectively formed on the plurality of first nanostructures 341, a plurality of second nanostructures 342, and second upper protective layers 342-1 respectively formed on the plurality of second nanostructures 342.

In addition, the substrate 310 may be a substrate in which a metal thin film 312 is coated on a silicon wafer 311.

According to one aspect, the lower plasmonic layer 320, the plurality of first nanostructures 341, and the plurality of second nanostructures 342 may comprise a first metal material, which may include silver (Ag). The plurality of first nanostructures 341 and the plurality of second nanostructures 342 may be formed to have a thickness in a range of 16 nm to 20 nm.

Preferably, the lower plasmonic layer 320 may be a silver (Ag) metal layer having a thickness of 30 nm, and each of the plurality of first nanostructures 341 and the plurality of second nanostructures 342 may be a silver (Ag) metal layer having a thickness of 18 nm.

The protective layer 330, the first upper protective layers 341-1, and the second upper protective layers 342-1 according to the embodiment may comprise at least one material selected from the group consisting of a second metal material, an oxide, and a nitride, and may be formed to have a thickness in a range of 2 nm to 10 nm.

For example, the second metal material may include at least one material selected from the group consisting of gold (Au), palladium (Pd), platinum (Pt), titanium (Ti), chromium (Cr), and nickel (Ni).

In addition, the oxide and nitride may include at least one material selected from the group consisting of silicon nitride (Si₃N₄), titanium nitride (TiN), silicon oxide (SiO₂), silicon oxynitride (SiON), aluminum oxide (Al₂O₃), chromium oxide (Cr₂O₃), nickel oxide (NiO₂), aluminum nitride (AlN), titanium nitride (TiN), and titanium oxide (TiO₂).

Preferably, the protective layer 330 may be a gold (Au) metal layer having a thickness of 10 nm, and the first upper protective layers 341-1 and the second upper protective layers 342-1 may each be gold (Au) metal layers having a thickness of 2 nm.

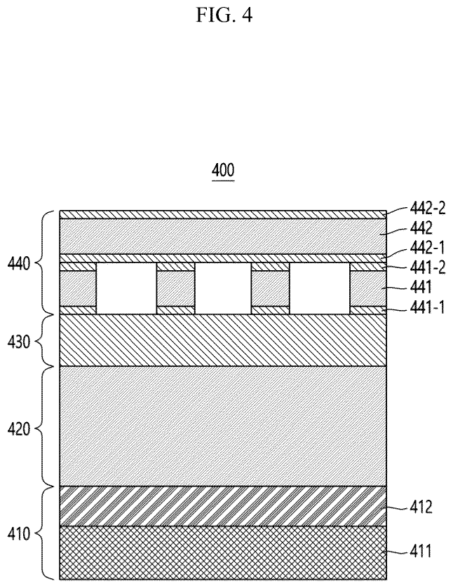

FIG. 4 is a view illustrating a surface-enhanced Raman scattering (SERS) substrate according to a third embodiment of the present invention.

Referring to FIG. 4, a SERS substrate 400 according to the third embodiment may be formed by stacking a substrate 410, a lower plasmonic layer 420, a protective layer 430, and an upper plasmonic layer 440.

According to one aspect, the upper plasmonic layer 440 may be formed by stacking a plurality of first nanostructures 441, first upper protective layers 441-1 respectively formed beneath each of the plurality of first nanostructures 441, second upper protective layers 441-2 respectively formed on top of each of the plurality of first nanostructures 441, a plurality of second nanostructures 442, third upper protective layers 442-1 respectively formed beneath each of the plurality of second nanostructures 442, and fourth upper protective layers 442-2 respectively formed on top of each of the plurality of second nanostructures 442.

In addition, the substrate 410 may be a substrate in which a metal thin film 412 is coated on a silicon wafer 411.

According to one aspect, the lower plasmonic layer 420, the plurality of first nanostructures 441, and the plurality of second nanostructures 442 may comprise a first metal material, which may include silver (Ag). The plurality of first nanostructures 441 and the plurality of second nanostructures 442 may be formed to have a thickness in a range of 16 nm to 20 nm.

Preferably, the lower plasmonic layer 420 may be a silver (Ag) metal layer having a thickness of 30 nm, and each of the plurality of first nanostructures 441 and the plurality of second nanostructures 442 may be silver (Ag) metal layers having a thickness of 16 nm.

The protective layer 430, the first upper protective layers 441-1, the second upper protective layers 441-2, the third upper protective layers 442-1, and the fourth upper protective layers 442-2 according to the embodiment may comprise at least one material selected from the group consisting of a second metal material, an oxide, and a nitride, and may be formed to have a thickness in a range of 2 nm to 10 nm.

For example, the second metal material may include at least one material selected from the group consisting of gold (Au), palladium (Pd), platinum (Pt), titanium (Ti), chromium (Cr), and nickel (Ni).

In addition, the oxide and nitride may include at least one material selected from the group consisting of silicon nitride (Si₃N₄), titanium nitride (TiN), silicon oxide (SiO₂), silicon oxynitride (SiON), aluminum oxide (Al₂O₃), chromium oxide (Cr₂O₃), nickel oxide (NiO₂), aluminum nitride (AlN), titanium nitride (TiN), and titanium oxide (TiO₂).

Preferably, the protective layer 430 may be a gold (Au) metal layer having a thickness of 10 nm, and the first upper protective layers 441-1, the second upper protective layers 441-2, the third upper protective layers 442-1, and the fourth upper protective layers 442-2 may each be gold (Au) metal layers having a thickness of 2 nm.

FIG. 5 is a view illustrating a surface-enhanced Raman scattering (SERS) substrate according to a fourth embodiment of the present invention.

Referring to FIG. 5, a SERS substrate 500 according to the fourth embodiment may be formed by stacking a substrate 510, a lower plasmonic layer 520, and an upper plasmonic layer 530 to form a laminated structure, and an oxidation-inhibiting layer 540 may be formed to surround the laminated structure.

According to one aspect, the upper plasmonic layer 530 may include a nanoarray structure in which a plurality of first nanostructures 531 formed in a first direction intersect with a plurality of second nanostructures 532 formed in a second direction orthogonal to the first direction.

In addition, the substrate 510 may be a substrate in which a metal thin film 512 is coated on a silicon wafer 511. Preferably, the metal thin film 512 may be a titanium (Ti) thin film having a thickness of 1 nm.

According to the embodiment, the lower plasmonic layer 520, and each of the plurality of first nanostructures 531 and the plurality of second nanostructures 532 constituting the upper plasmonic layer 530 may comprise a first metal material, which may include silver (Ag). Preferably, the lower plasmonic layer 520 may be a silver (Ag) metal layer having a thickness of 30 nm, and each of the plurality of first nanostructures 531 and the plurality of second nanostructures 532 may be silver (Ag) metal layers having a thickness of 20 nm.

The oxidation-inhibiting layer 540 according to the embodiment may comprise at least one material selected from the group consisting of a second metal material, an oxide, and a nitride, and may be formed to have a thickness in a range of 2 nm to 4 nm.

For example, the second metal material may include at least one material selected from the group consisting of gold (Au), palladium (Pd), platinum (Pt), titanium (Ti), chromium (Cr), and nickel (Ni).

In addition, the oxide and nitride may include at least one material selected from the group consisting of silicon nitride (Si₃N₄), titanium nitride (TiN), silicon oxide (SiO₂), silicon oxynitride (SiON), aluminum oxide (Al₂O₃), chromium oxide (Cr₂O₃), nickel oxide (NiO₂), aluminum nitride (AlN), titanium nitride (TiN), and titanium oxide (TiO₂).

Preferably, the oxidation-inhibiting layer 540 may be a gold (Au) metal layer having a thickness in a range of 2 nm to 4 nm, or a silicon oxide (SiO₂) layer having a thickness in a range of 2 nm to 4 nm.

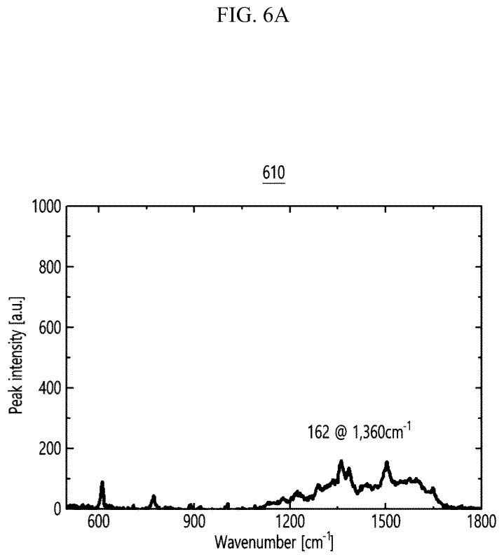

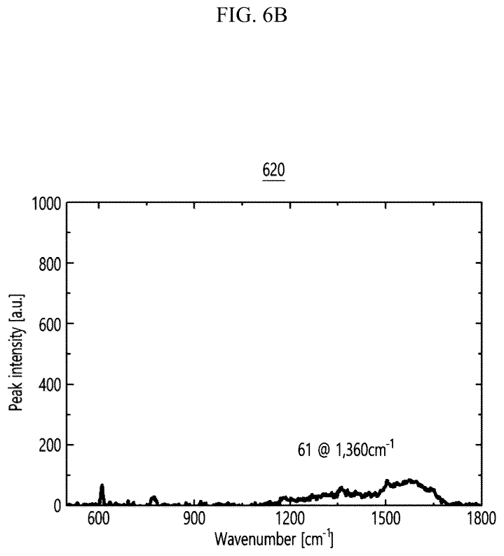

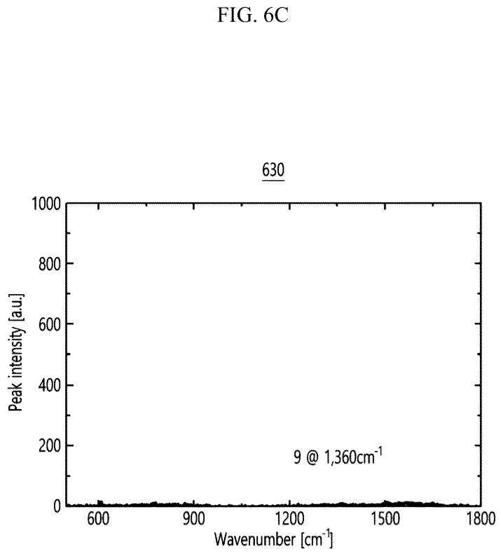

FIGS. 6A to 6C are views illustrating measurement results of background peaks for surface-enhanced Raman scattering (SERS) substrates according to the first to third embodiments of the present invention.

Referring to FIGS. 6A to 6C, reference numeral 610 illustrates the measurement result of the background peak for the SERS substrate according to the first embodiment, reference numeral 620 illustrates the measurement result of the background peak for the SERS substrate according to the second embodiment, and reference numeral 630 illustrates the measurement result of the background peak for the SERS substrate according to the third embodiment.

In this case, the SERS substrate according to the first embodiment was tested by applying a 30 nm-thick silver (Ag) metal layer (i.e., lower plasmonic layer) and a 10 nm-thick gold (Au) metal layer (i.e., protective layer).

In addition, the SERS substrate according to the second embodiment was tested by applying a 30 nm-thick silver (Ag) metal layer (i.e., lower plasmonic layer), a 10 nm-thick gold (Au) metal layer (i.e., protective layer), 18 nm-thick silver (Ag) metal layers (i.e., first and second nanostructures), and 2 nm-thick gold (Au) metal layers (i.e., first and second upper protective layers).

Further, the SERS substrate according to the third embodiment was tested by applying a 30 nm-thick silver (Ag) metal layer (i.e., lower plasmonic layer), a 10 nm-thick gold (Au) metal layer (i.e., protective layer), 16 nm-thick silver (Ag) metal layers (i.e., first and second nanostructures), and 2 nm-thick gold (Au) metal layers (i.e., first to fourth upper protective layers).

According to reference numerals 610 to 630, the background peaks for the SERS substrates according to the first to third embodiments were measured as ‘162’, ‘61’, and ‘9’, respectively, indicating that all of the background peaks were effectively reduced compared to the Ag-based SERS substrate without a protective layer (background peak: 542).

In addition, while the SERS performance of the SERS substrates according to the first to third embodiments was found to be slightly lower than that of the Ag-based SERS substrate without a protective layer, the sensitivity was improved by approximately eight times compared to a gold (Au)-based SERS substrate.

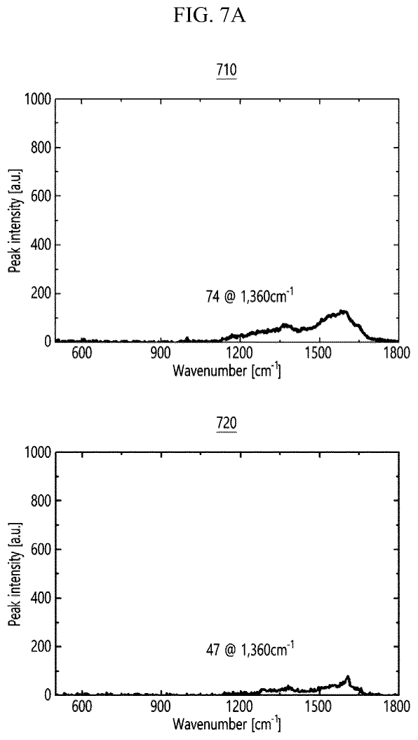

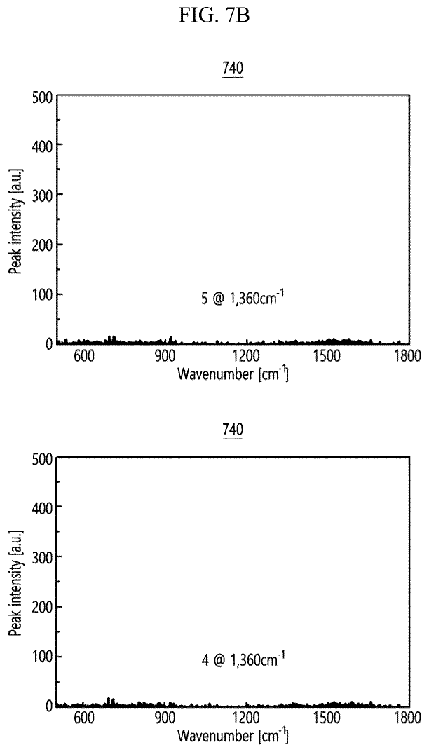

FIGS. 7A and 7B are views illustrating measurement results of background peaks for a surface-enhanced Raman scattering (SERS) substrate according to a fourth embodiment of the present invention.

Referring to FIGS. 7A and 7B, reference numeral 710 illustrates the background peak measurement result of a SERS substrate comprising a 2 nm-thick gold (Au) metal layer as an oxidation-inhibiting layer, and reference numeral 720 illustrates the background peak measurement result of a SERS substrate comprising a 4 nm-thick gold (Au) metal layer as an oxidation-inhibiting layer.

In addition, reference numeral 730 illustrates the background peak measurement result of a SERS substrate comprising a 2 nm-thick silicon oxide (SiO₂) layer as an oxidation-inhibiting layer, and reference numeral 740 illustrates the background peak measurement result of a SERS substrate comprising a 4 nm-thick silicon oxide (SiO₂) layer as an oxidation-inhibiting layer.

According to reference numerals 710 to 740, when the oxidation-inhibiting layer of the SERS substrate is formed with a 2 nm-thick silicon oxide (SiO₂) layer, a 4 nm-thick silicon oxide (SiO₂) layer, a 2 nm-thick gold (Au) metal layer, or a 4 nm-thick gold (Au) metal layer, the measured background peaks are ‘74’, ‘47’, ‘5’, and ‘4’, respectively, indicating that the background peaks were all effectively reduced compared to a silver (Ag)-based SERS substrate without a protective layer (background peak: 542).

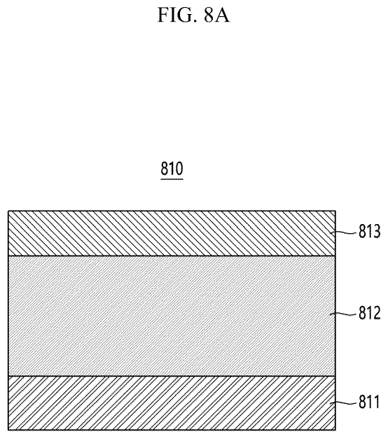

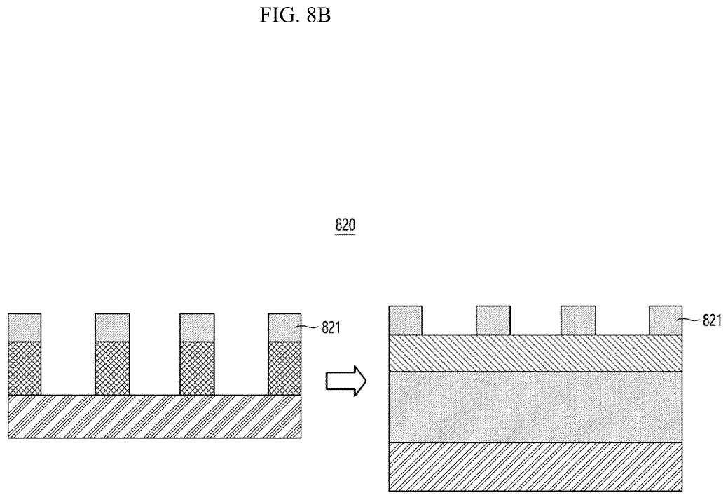

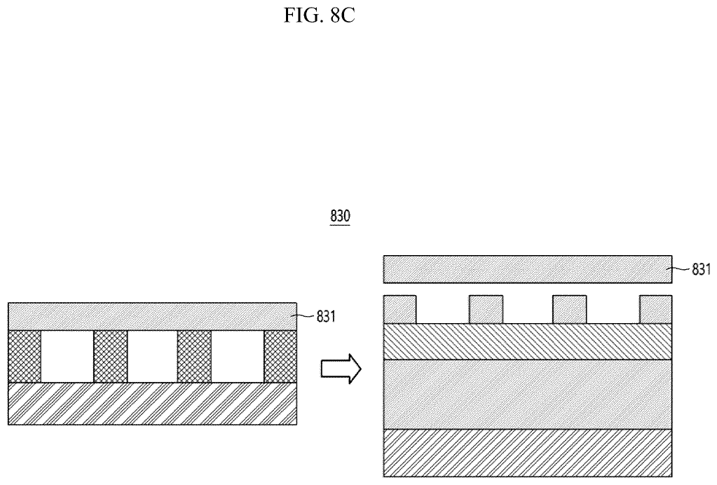

FIGS. 8A to 8C are views illustrating a method of manufacturing a surface-enhanced Raman scattering (SERS) substrate according to a first embodiment of the present invention.

Referring to FIGS. 8A to 8C, in step 810, the method may include forming a lower plasmonic layer 812 comprising a first metal material on a substrate 811, and forming a protective layer 813 on the lower plasmonic layer 812, the protective layer comprising at least one material selected from the group consisting of a second metal material, an oxide, and a nitride.

For example, the first metal material may include silver (Ag), and the second metal material may include at least one material selected from the group consisting of gold (Au), palladium (Pd), platinum (Pt), titanium (Ti), chromium (Cr), and nickel (Ni).

In addition, the oxide and nitride may include at least one material selected from the group consisting of silicon nitride (Si₃N₄), titanium nitride (TiN), silicon oxide (SiO₂), silicon oxynitride (SiON), aluminum oxide (Al₂O₃), chromium oxide (Cr₂O₃), nickel oxide (NiO₂), aluminum nitride (AlN), titanium nitride (TiN), and titanium oxide (TiO₂).

According to one aspect, in step 810, the method may include forming the lower plasmonic layer 812 and the protective layer 813 by using at least one of physical vapor deposition (PVD), chemical vapor deposition (CVD), atomic layer deposition (ALD), sputtering, thermal evaporation, or electron beam (e-beam) evaporation.

Next, in steps 820 and 830, the method may include forming an upper plasmonic layer 821, 831 on the protective layer 813, the upper plasmonic layer comprising a three-dimensional nanostructure based on the first metal material.

Specifically, in step 820, the method may include forming a plurality of first nanostructures 821 in a first direction on the protective layer 813, and in step 830, the method may include forming a plurality of second nanostructures 831 in a second direction orthogonal to the first direction, on the plurality of first nanostructures 821.

For example, in steps 820 and 830, the method may include forming the plurality of first nanostructures 821 and the plurality of second nanostructures 831 using a nanoimprinting process based on a polymer mold replicated from a master mold pattern, wherein the polymer mold may include poly(methyl methacrylate) (PMMA).

That is, in step 820, the method may include transferring the plurality of first nanostructures 821 onto the protective layer 813 using the nanoimprinting process, and in step 830, the method may include transferring the plurality of second nanostructures 831 onto the plurality of first nanostructures 821 using the nanoimprinting process.

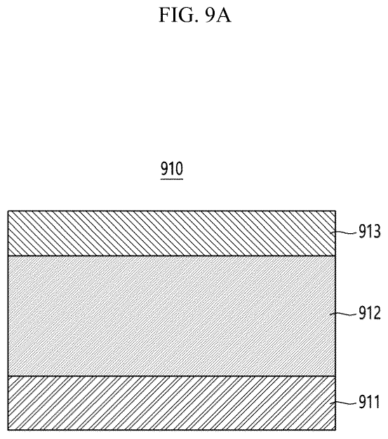

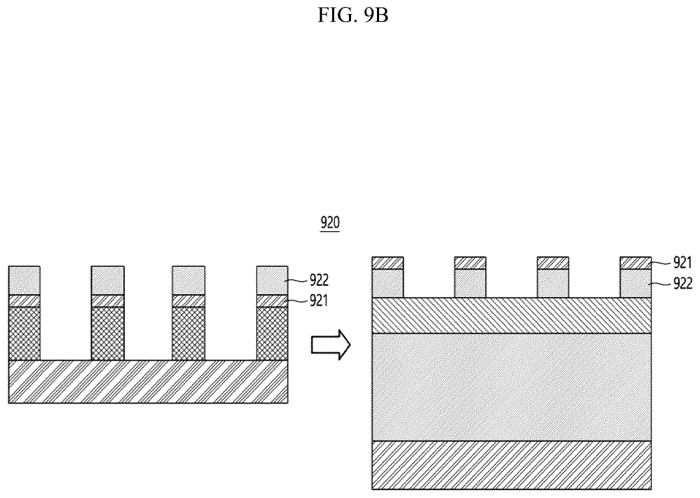

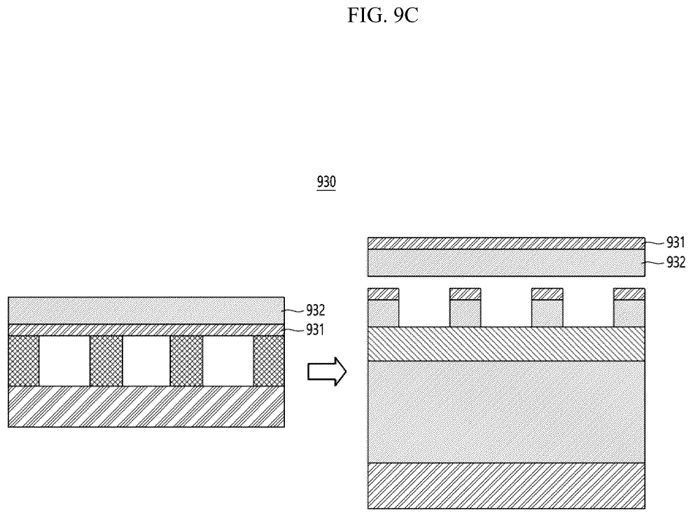

FIGS. 9A to 9C are views illustrating a method of manufacturing a surface-enhanced Raman scattering (SERS) substrate according to a second embodiment of the present invention.

Referring to FIGS. 9A to 9C, in step 910, the method may include forming a lower plasmonic layer 912 comprising a first metal material on a substrate 911, and forming a protective layer 913 on the lower plasmonic layer 912, the protective layer comprising at least one material selected from the group consisting of a second metal material, an oxide, and a nitride.

For example, the first metal material may include silver (Ag), and the second metal material may include at least one material selected from the group consisting of gold (Au), palladium (Pd), platinum (Pt), titanium (Ti), chromium (Cr), and nickel (Ni).

In addition, the oxide and nitride may include at least one material selected from the group consisting of silicon nitride (Si₃N₄), titanium nitride (TiN), silicon oxide (SiO₂), silicon oxynitride (SiON), aluminum oxide (Al₂O₃), chromium oxide (Cr₂O₃), nickel oxide (NiO₂), aluminum nitride (AlN), titanium nitride (TiN), and titanium oxide (TiO₂).

According to one aspect, in step 910, the method may include forming the lower plasmonic layer 912 and the protective layer 913 by using at least one of physical vapor deposition (PVD), chemical vapor deposition (CVD), atomic layer deposition (ALD), sputtering, thermal evaporation, or electron beam (e-beam) evaporation.

Subsequently, in steps 920 and 930, the method may include forming an upper plasmonic layer 921, 922, 931, 932 comprising a three-dimensional nanostructure based on the first metal material on the protective layer 913.

Specifically, in step 920, the method may include forming a plurality of first nanostructures 922 having a first upper protective layer 921 formed thereon on the protective layer 913. In step 930, the method may include forming a plurality of second nanostructures 932 having a second upper protective layer 931 formed thereon on the plurality of first nanostructures 922 having the first upper protective layer 921 formed thereon.

For example, in steps 920 and 930, the method may include forming the plurality of first nanostructures 922 with the first upper protective layer 921 and the plurality of second nanostructures 932 with the second upper protective layer 931 by using a nanoimprinting process based on a polymer mold replicated from a master mold pattern.

That is, in step 920, the method may include transferring the plurality of first nanostructures 922 with the first upper protective layer 921 onto the protective layer 913 using the nanoimprinting process, and in step 930, the method may include transferring the plurality of second nanostructures 932 with the second upper protective layer 931 onto the first upper protective layer 921 using the nanoimprinting process.

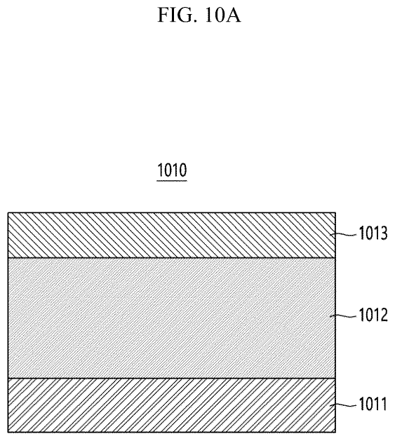

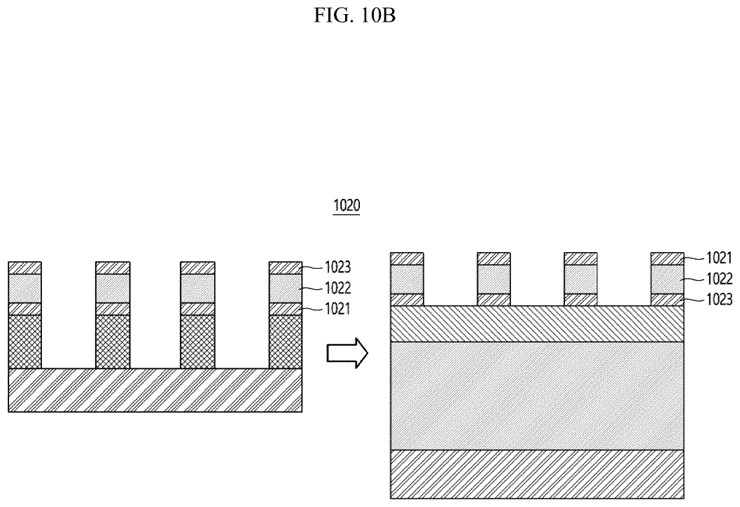

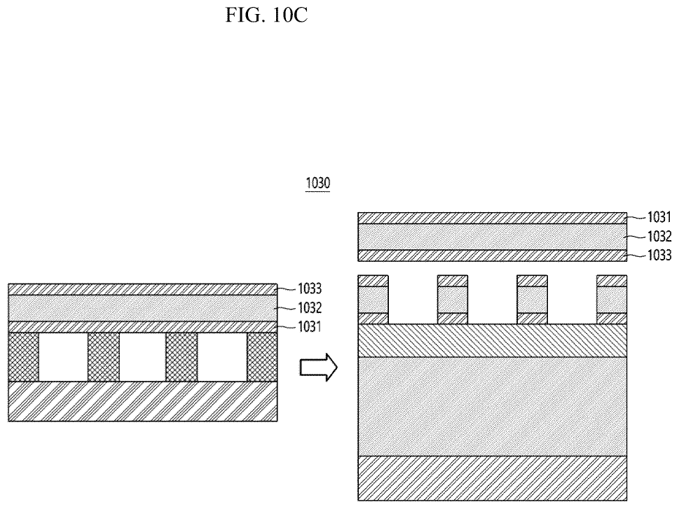

FIGS. 10A to 10C are views illustrating a method of manufacturing a surface-enhanced Raman scattering (SERS) substrate according to a third embodiment of the present invention.

Referring to FIGS. 10A to 10C, in step 1010, the method may include forming a lower plasmonic layer 1012 comprising a first metal material on a substrate 1011, and forming a protective layer 1013 on the lower plasmonic layer 1012, the protective layer comprising at least one material selected from the group consisting of a second metal material, an oxide, and a nitride.

For example, the first metal material may include silver (Ag), and the second metal material may include at least one material selected from the group consisting of gold (Au), palladium (Pd), platinum (Pt), titanium (Ti), chromium (Cr), and nickel (Ni).

In addition, the oxide and nitride may include at least one material selected from the group consisting of silicon nitride (Si₃N₄), titanium nitride (TiN), silicon oxide (SiO₂), silicon oxynitride (SiON), aluminum oxide (Al₂O₃), chromium oxide (Cr₂O₃), nickel oxide (NiO₂), aluminum nitride (AlN), titanium nitride (TiN), and titanium oxide (TiO₂).

According to one aspect, in step 1010, the method may include forming the lower plasmonic layer 1012 and the protective layer 1013 by using at least one of physical vapor deposition (PVD), chemical vapor deposition (CVD), atomic layer deposition (ALD), sputtering, thermal evaporation, and electron beam (e-beam) evaporation.

Next, in steps 1020 and 1030, the method may include forming an upper plasmonic layer 1021 to 1023, 1031 to 1033 comprising three-dimensional nanostructures based on the first metal material on the protective layer 1013.

Specifically, in step 1020, the method may include forming a plurality of first nanostructures 1022 on the protective layer 1013, the plurality of first nanostructures 1022 having a first upper protective layer 1023 and a second upper protective layer 1021 formed on lower and upper surfaces thereof, respectively.

In step 1030, the method may include forming a plurality of second nanostructures 1032 on the plurality of first nanostructures 1022, the plurality of second nanostructures 1032 having a third upper protective layer 1033 and a fourth upper protective layer 1031 formed on lower and upper surfaces thereof, respectively.

For example, in steps 1020 and 1030, the method may include forming the plurality of first nanostructures 1022 having the first upper protective layer 1023 and the second upper protective layer 1021 and the plurality of second nanostructures 1032 having the third upper protective layer 1033 and the fourth upper protective layer 1031 by using a nanoimprinting method based on a polymer mold replicated from a master mold pattern.

That is, in step 1020, the method may include transferring the plurality of first nanostructures 1022 having the first upper protective layer 1023 and the second upper protective layer 1021 onto the protective layer 1013 using the nanoimprinting method, and in step 1030, the method may include transferring the plurality of second nanostructures 1032 having the third upper protective layer 1033 and the fourth upper protective layer 1031 onto the second upper protective layer 1021 using the nanoimprinting method.

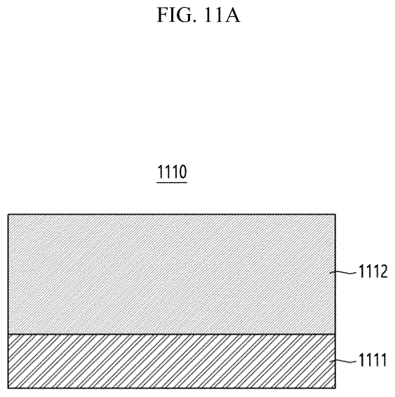

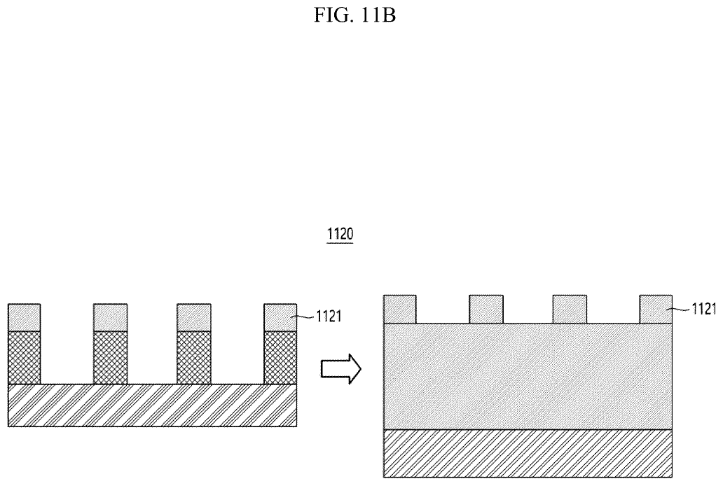

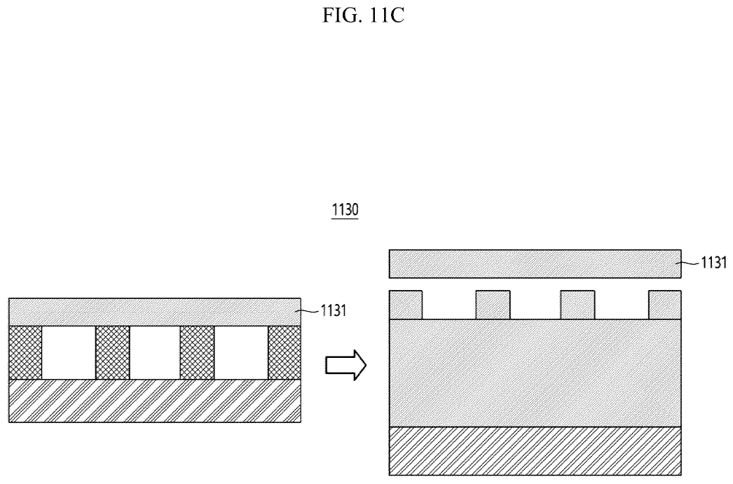

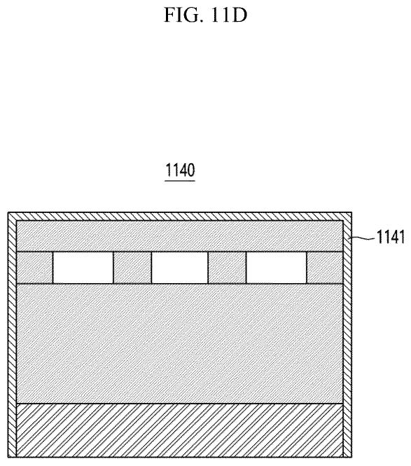

FIGS. 11A to 11D are views illustrating a method of manufacturing a surface-enhanced Raman scattering (SERS) substrate according to a fourth embodiment of the present invention.

Referring to FIGS. 11A to 11D, in step 1110, the method may include forming a lower plasmonic layer 1112 comprising a first metal material on a substrate 1111.

For example, the first metal material may include silver (Ag), and in step 1110, the lower plasmonic layer 1112 may be formed using at least one of physical vapor deposition (PVD), chemical vapor deposition (CVD), atomic layer deposition (ALD), sputtering, thermal evaporation, and electron beam (e-beam) evaporation.

Next, in steps 1120 and 1130, the method may include forming an upper plasmonic layer (1121 and 1131) comprising three-dimensional nanostructures based on the first metal material on the lower plasmonic layer 1112.

Specifically, in step 1120, the method may include forming a plurality of first nanostructures 1121 on the lower plasmonic layer 1112 in a first direction, and in step 1130, the method may include forming a plurality of second nanostructures 1131 on the plurality of first nanostructures 1121 in a second direction orthogonal to the first direction.

For example, in steps 1120 and 1130, the method may include forming the plurality of first nanostructures 1121 and the plurality of second nanostructures 1131 using a nanoimprinting method based on a polymer mold replicated from a master mold pattern, wherein the polymer mold may include poly(methyl methacrylate) (PMMA).

That is, in step 1120, the method may include transferring the plurality of first nanostructures 1121 onto the lower plasmonic layer 1112 by a nanoimprinting method, and in step 1130, the method may include transferring the plurality of second nanostructures 1131 onto the plurality of first nanostructures 1121 by the nanoimprinting method.

Next, in step 1140, the method may include forming an oxidation-inhibition layer 1141 comprising at least one of a second metal material, an oxide, or a nitride so as to surround the stacked structure of the substrate 1111, the lower plasmonic layer 1112, and the upper plasmonic layers 1121 and 1131.

For example, the second metal material may include at least one of gold (Au), palladium (Pd), platinum (Pt), titanium (Ti), chromium (Cr), and nickel (Ni).

Also, the oxide and nitride may include at least one of silicon nitride (Si₃N₄), titanium nitride (TiN), silicon oxide (SiO₂), silicon oxynitride (SiON), aluminum oxide (Al₂O₃), chromium oxide (Cr₂O₃), nickel oxide (NiO₂), aluminum nitride (AlN), titanium nitride (TiN), and titanium oxide (TiO₂).

According to one embodiment, in step 1140, the oxidation-inhibition layer 1141 may be formed using at least one of physical vapor deposition (PVD), chemical vapor deposition (CVD), atomic layer deposition (ALD), sputtering, thermal evaporation, and electron beam evaporation (e-beam evaporation), and the oxidation-inhibition layer 1141 may have a thickness of 2 nm to 4 nm.

In some cases, in step 1140, the method may further include dividing the stacked structure into a predetermined chip-scale and then forming the oxidation-inhibition layer 1141 on each of the divided chips.

As a result, the present invention may provide a high-performance surface-enhanced Raman scattering (SERS) substrate with excellent signal uniformity and reproducibility.

In addition, the present invention may minimize background peak formation by applying a protective layer to prevent oxidation of the metal material constituting the plasmonic layer.

Moreover, the present invention may minimize background peak formation by applying an oxidation-inhibition layer to prevent oxidation of the metal material constituting the plasmonic layer.

Although the embodiments have been described with reference to limited drawings, various modifications and alterations may be made by those skilled in the art based on the above disclosure.

For example, the described techniques may be performed in an order different from that described, and/or the components such as the devices, structures, apparatuses, and circuits described may be combined or configured in forms different from those described, or substituted with other components or equivalents to achieve similar results.

Therefore, other implementations, other embodiments, and equivalents of the claims fall within the scope of the following claims.

1. A surface-enhanced Raman scattering (SERS) substrate comprising:
a substrate;
a lower plasmonic layer formed on the substrate and comprising a first metal material;
a protective layer formed on the lower plasmonic layer and comprising at least one material selected from the group consisting of a second metal material, an oxide, and a nitride; and
an upper plasmonic layer formed on the protective layer and comprising a three-dimensional nanostructure based on the first metal material.

2. The SERS substrate according to claim 1,
wherein the first metal material comprises silver (Ag).

3. The SERS substrate according to claim 1,
wherein the second metal material comprises at least one material selected from the group consisting of gold (Au), palladium (Pd), platinum (Pt), titanium (Ti), chromium (Cr), and nickel (Ni).

4. The SERS substrate according to claim 1,
wherein the oxide and nitride comprise at least one material selected from the group consisting of silicon nitride (Si₃N₄), titanium nitride (TiN), silicon oxide (SiO₂), silicon oxynitride (SiON), aluminum oxide (Al₂O₃), chromium oxide (Cr₂O₃), nickel oxide (NiO₂), aluminum nitride (AlN), titanium nitride (TiN), and titanium oxide (TiO₂).

5. The SERS substrate according to claim 1,
wherein the protective layer is formed on the lower plasmonic layer to have a thickness in a range of 2 nm to 10 nm.

6. The SERS substrate according to claim 1,
wherein the three-dimensional nanostructure comprises a nanoarray structure in which a plurality of first nanostructures formed in a first direction intersect with a plurality of second nanostructures formed in a second direction orthogonal to the first direction.

7. The SERS substrate according to claim 6,
wherein each of the plurality of first nanostructures and the plurality of second nanostructures is formed to have a thickness in a range of 16 nm to 20 nm.

8. The SERS substrate according to claim 6,
wherein the upper plasmonic layer further comprises:
a first upper protective layer formed on each of the plurality of first nanostructures; and
a second upper protective layer formed on each of the plurality of second nanostructures.

9. The SERS substrate according to claim 6,
wherein the upper plasmonic layer further comprises:
a first upper protective layer formed beneath each of the plurality of first nanostructures;
a second upper protective layer formed on each of the plurality of first nanostructures;
a third upper protective layer formed beneath each of the plurality of second nanostructures; and
a fourth upper protective layer formed on each of the plurality of second nanostructures.

10. The SERS substrate according to claim 1,
wherein the substrate is a substrate comprising a metal thin film coated on a silicon wafer.

11. A method of manufacturing a surface-enhanced Raman scattering (SERS) substrate, the method comprising:
forming a lower plasmonic layer comprising a first metal material on a substrate;
forming a protective layer comprising at least one material selected from the group consisting of a second metal material, an oxide, and a nitride on the lower plasmonic layer; and
forming an upper plasmonic layer comprising a three-dimensional nanostructure based on the first metal material on the protective layer.

12. The method of claim 11,
wherein forming the upper plasmonic layer comprises:
forming a plurality of first nanostructures in a first direction on the protective layer; and
forming a plurality of second nanostructures in a second direction orthogonal to the first direction on the plurality of first nanostructures.

13. The method of claim 12,
wherein forming the plurality of first nanostructures comprises forming the plurality of first nanostructures each having a first upper protective layer on a top thereof on the protective layer; and
wherein forming the plurality of second nanostructures comprises forming the plurality of second nanostructures each having a second upper protective layer on a top thereof on the plurality of first nanostructures having the first upper protective layer.

14. The method of claim 12,
wherein forming the plurality of first nanostructures comprises forming the plurality of first nanostructures each having a first upper protective layer on a bottom thereof and a second upper protective layer on a top thereof on the protective layer; and
wherein forming the plurality of second nanostructures comprises forming the plurality of second nanostructures each having a third upper protective layer on a bottom thereof and a fourth upper protective layer on a top thereof on the plurality of first nanostructures having the first and second upper protective layers.
